(19) United States
(12) Patent Application Publication
(10) Pub. No.: US 2026/0123525 A1
(43) Pub. Date: Apr. 30, 2026

(54) SEMICONDUCTOR STRUCTURE WITH BONDING STRUCTURE AND METHOD OF FORMING THE SAME

(71) Applicant: Taiwan Semiconductor Manufacturing Company, Ltd., Hsinchu (TW)

(72) Inventors: Che Wei Yang, New Taipei City (TW); Ming-Che Lee, Tainan City (TW); Sheng-Chau CHEN, Tainan City (TW); Chung-Yi Yu, Hsin-Chu (TW); Cheng-Yuan Tsai, Hsin-Chu county (TW)

(73) Assignee: Taiwan Semiconductor Manufacturing Company, Ltd., Hsinchu (TW)

(21) Appl. No.: 18/924,926

(22) Filed: Oct. 23, 2024

(51) Int. Cl. H01L 23/00; H01L 25/065

(52) U.S. Cl. CPC H10W 90/00; H10W 72/01935; H10W 72/01951; H10W 72/923; H10W 72/951; H10W 72/952; H10W 80/102; H10W 80/312; H10W 80/327; H10W 90/792

(57) ABSTRACT

Provided is a bonding structure including a first dielectric layer, a first non-twinned metal layer, a first twinned metal layer, and a first transition layer. The first dielectric layer has a first inner sidewall defining a first via hole and a first trench on the first via hole. The first non-twinned metal layer is filled in the first via hole. The first twinned metal layer is disposed over the first non-twinned metal layer and within the first trench. The first transition layer is sandwiched between the first non-twinned metal layer and the first twinned metal layer.

### BACKGROUND

The semiconductor industry has experienced rapid growth due to ongoing improvements in the integration density of a variety of electronic components (e.g., transistors, diodes, resistors, capacitors, and the like). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

As semiconductor technologies further advance, stacked and bonded semiconductor devices have emerged as an effective alternative to further reduce the physical size of a semiconductor device. In a stacked semiconductor device, active circuits such as logic, memory, processor circuits and the like are fabricated at least partially on separate substrates and then physically and electrically bonded together in order to form a functional device. Such bonding processes utilize sophisticated techniques, and improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of a semiconductor structure in accordance with some embodiments.

FIG. 1B illustrates a perspective view of a first tier bonding to a second tier in accordance with some embodiments.

FIG. 1C illustrates an enlarged cross-sectional view of a region of a semiconductor structure of FIG. 1A in accordance with some embodiments.

FIG. 2A to FIG. 2D illustrate cross-sectional views of intermediate stages in the formation of a semiconductor structure in accordance with some embodiments.

FIG. 2E-FIG. 2G are various views of a bonding structure in accordance with some embodiments.

FIG. 3 is a cross-sectional view of a semiconductor structure, in accordance with some embodiments.

FIG. 4A and FIG. 4B illustrate a cross-sectional view and a top view of a semiconductor structure in accordance with some alternative embodiments.

FIG. 5A to FIG. 5D illustrate cross-sectional views of intermediate stages in the formation of a semiconductor structure in accordance with some other embodiments.

FIG. 6 illustrates a cross-sectional view of a semiconductor structure in accordance with some alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

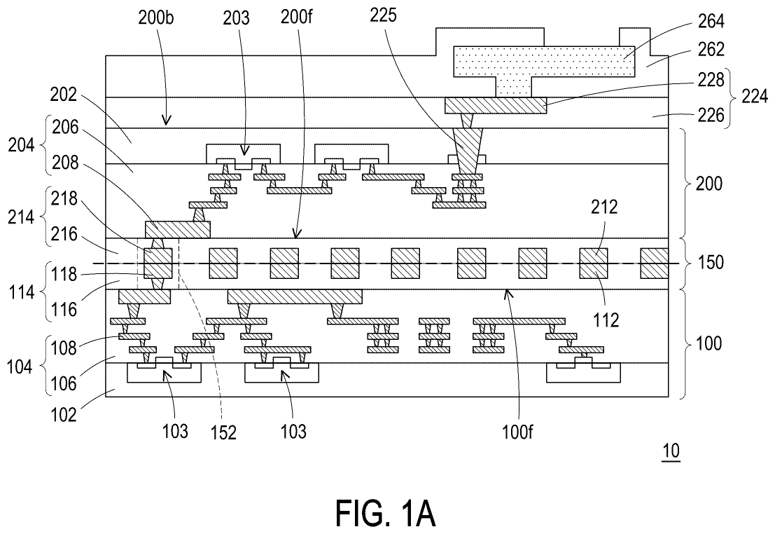

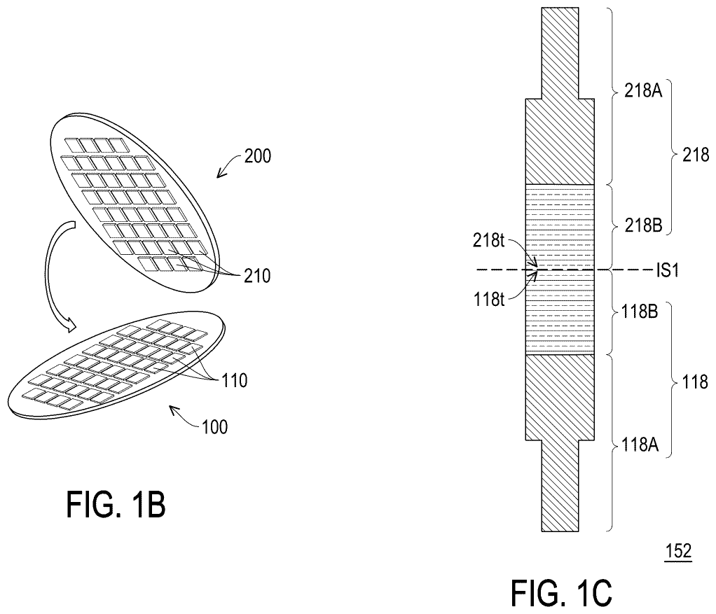

FIG. 1A illustrates a cross-sectional view of a semiconductor structure in accordance with some embodiments. FIG. 1B illustrates a perspective view of a first tier bonding to a second tier in accordance with some embodiments.

Referring to FIG. 1A, a semiconductor structure 10 is provided. In some embodiments, the semiconductor structure 10 includes a first tier 100, a second tier 200, and a bonding structure 150. The first tier 100 may be bonded to the second tier 200 by the bonding structure 150.

Specifically, the first tier 100 may include a first semiconductor substrate 102, a first device region 103, a first interconnect structure 104, and a first bonding layer 114. In some embodiments, the first tier 100 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), the like, or combinations thereof (e.g., a system-on-a-chip (SoC) die). In the present embodiment, the first tier 100 is a semiconductor wafer having a plurality of die regions 110 arranged in a plurality of rows and a plurality of columns, as shown in FIG. 1B.

In some embodiments, the first semiconductor substrate 102 may include silicon or other semiconductor materials. Alternatively, or additionally, the first semiconductor substrate 102 may include other elementary semiconductor materials such as germanium. In some embodiments, the first semiconductor substrate 102 is made of a compound semiconductor such as silicon carbide, gallium arsenic, indium arsenide or indium phosphide. In some embodiments, the first semiconductor substrate 102 is made of an alloy semiconductor such as silicon germanium, silicon germanium carbide, gallium arsenic phosphide, or gallium indium phosphide. In some embodiments, the first semiconductor substrate 102 includes an epitaxial layer. For example, the first semiconductor substrate 102 has an epitaxial layer overlying a bulk semiconductor.

In some embodiments, the first device region 103 is formed on the first semiconductor substrate 102 in a front-end-of-line (FEOL) process. The first device region 103 includes a wide variety of devices. In some embodiments, the devices comprise active components, passive components, or a combination thereof. In some embodiments, the devices may include integrated circuits devices. The devices are, for example, transistors, capacitors, resistors, diodes, photodiodes, fuse devices, or other similar devices. In some embodiments, the first device region 103 includes a gate structure, source/drain regions, and isolation structures, such as shallow trench isolation (STI) structures (not shown). The first device region 103 shown in FIG. 1A are merely examples, and other structures may be formed in the first device region 103. In the first device region 103, various N-type metal-oxide semiconductor (NMOS) and/or P-type metal-oxide semiconductor (PMOS) devices, such as transistors or memories and the like, may be formed and interconnected to perform one or more functions. Other devices, such as capacitors, resistors, diodes, photodiodes, fuses and the like may also be formed on the first semiconductor substrate 102. The functions of the devices may include memory, processors, sensors, amplifiers, power distribution, input/output circuitry, or the like.

In some embodiments, the first interconnect structure 104 is formed over the first semiconductor substrate 102. In detail, the first interconnect structure 104 includes a first insulating material 106 and a plurality of first metal features 108. The first metal features 108 are formed in the first insulating material 106 and electrically connected with each other. In some embodiments, the first insulating material 106 includes an inner-layer dielectric (ILD) layer on the first semiconductor substrate 102, and at least one inter-metal dielectric (IMD) layer over the inner-layer dielectric layer. In some embodiments, the first insulating material 106 includes silicon oxide, silicon oxynitride, silicon nitride, low dielectric constant (low-k) materials or a combination thereof. In some alternatively embodiments, the first insulating material 106 may be a single layer or multiple layers. In some embodiments, the first metal features 108 include plugs and metal lines. The plugs may include contacts formed in the inner-layer dielectric layer, and vias formed in the inter-metal dielectric layer. The contacts are formed between and in connect with the substrate 102 and a bottom metal line. The vias are formed between and in connect with two metal lines. The first metal features 108 may be made of tungsten (W), copper (Cu), copper alloys, aluminum (Al), aluminum alloys, or a combination thereof. In some alternatively embodiments, a barrier layer (not shown) may be formed between the first metal features 108 and the first insulating material 106 to prevent the material of the first metal features 108 from migrating to the first device region 103. A material of the barrier layer includes tantalum, tantalum nitride, titanium, titanium nitride, cobalt-tungsten (CoW) or a combination thereof, for example.

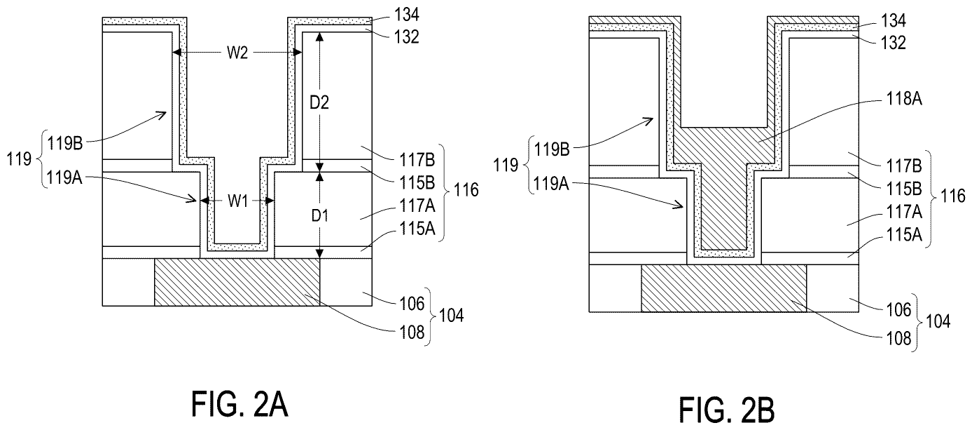

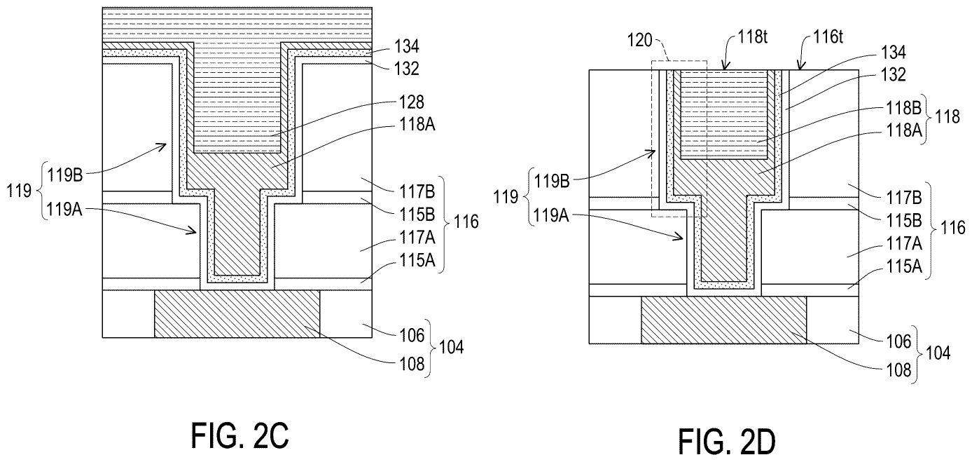

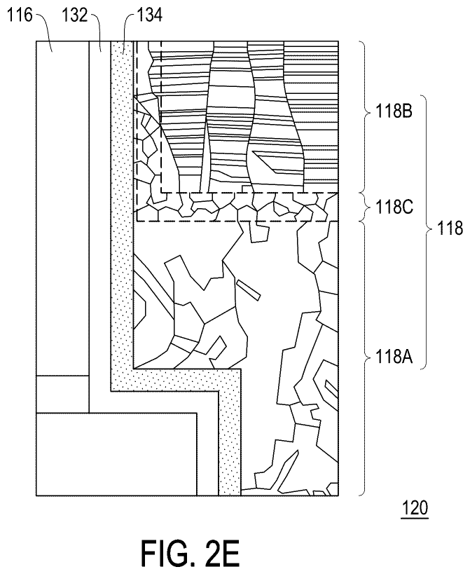

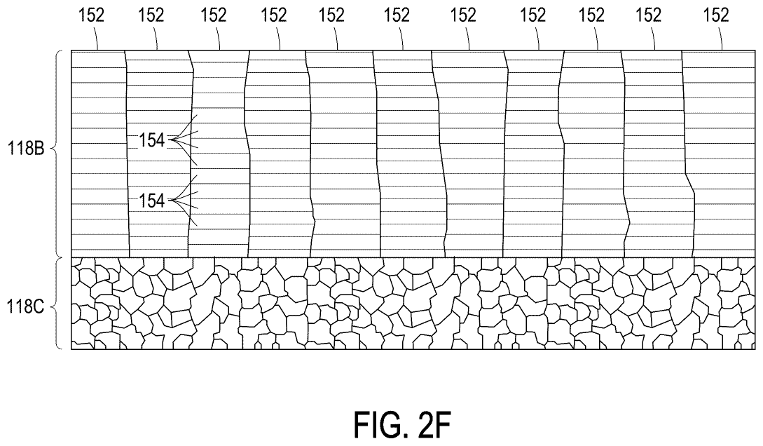

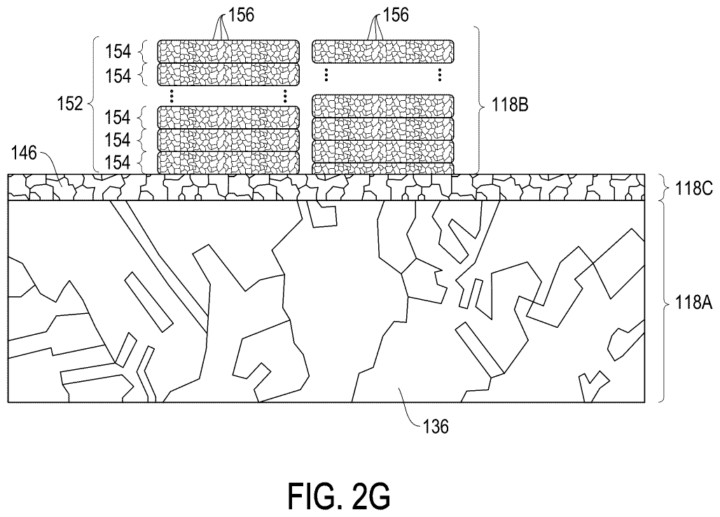

In some embodiments, the first bonding layer 114 is formed over the first interconnect structure 104. In detail, the first bonding layer 114 may include a first dielectric layer 116 and a first metal layer 118 embedded in the first dielectric layer 116. In some embodiments, the first dielectric layer 116 may be formed of a polymer such as polybenzoxazole (PBO), polyimide, a benzocyclobutene (BCB)-based polymer, or the like; a nitride such as silicon nitride or the like; an oxide such as silicon oxide, phosphosilicate glass (PSG), borosilicate glass (BSG), boron-doped phosphosilicate glass (BPSG), a tetraethyl orthosilicate (TEOS) based oxide; the like, or a combination thereof. The first dielectric layer 116 may be formed, for example, by spin coating, lamination, CVD, or the like. In the present embodiments, the first dielectric layer 116 is form of TEOS-based silicon oxide. In some embodiments, the first metal layer 118 includes a via plug and a metal plate over the via plug. In some other embodiments, the metal plate is a via plug having a larger area than the underlying via plug. In some embodiments, the first metal layer 118 is formed of copper. The crystal structure of the first metal layer 118 will be subsequently described for FIGS. 2A-FIG. 2G. In some other embodiments, the first metal layer 118 s formed of another conductive material, such as tungsten (W), cobalt (Co), or a combination thereof. Further, the first bonding layer 114 may include a first dummy metal layer 112 embedded in the first dielectric layer 116. The first dummy metal layer 112 and the first metal layer 118 may have the same material and may be formed in the same step.

Referring to FIG. 1A, a second tier 200 is provided to bond onto the first tier 100. The second tier 200 and the first tier 100 may be the same types of integrated circuits (ICs) or different types of ICs. In some embodiments, the second tier 200 is similar to the first tier 100. That is, the second tier 200 includes a second semiconductor substrate 202, a second device region 203, a second interconnect structure 204 with a second insulating material 206 and a plurality of second metal features 208, and a second bonding layer 214 with a second dielectric layer 216, a second metal layer 218, and a second dummy metal layer 212. The arrangement, material and forming method of the second tier 200 are similar to the arrangement, material and forming method of the first tier 100. Thus, details thereof are omitted here. In the present embodiment, the second tier 200 is a semiconductor wafer having a plurality of die regions 210 arranged in a plurality of rows and a plurality of columns, as shown in FIG. 1B.

In some embodiments, the second tier 200 is bonded onto the first tier 100 by directing contacting the second bonding layer 214 with the first bonding layer 114. Specifically, the second tier 200 is bonded onto the first tier 100 by face-to-face bonding. That is, a frontside 200f of the second tier 200 may face toward a frontside 100f of the first tier 100, and the second bonding layer 214 is in direct contact with the first bonding layer 114 to form the bonding structure 150 for bonding the second tier 200 with the first tier 100. In some embodiments, the bonding structure 150 may involve at least two types of bonding, including metal-to-metal bonding and non-metal-to-non-metal bonding such as dielectric-to-dielectric bonding or fusion bonding. As shown in FIG. 1A, the bonding structure 150 includes the first dummy metal layer 112 and the second dummy metal layer 212 bonded by metal-to-metal bonding, the first metal layer 118 and the second metal layer 218 bonded by metal-to-metal bonding, and the first dielectric layer 116 and the second dielectric layer 216 bonded by non-metal-to-non-metal bonding.

After bonding the second tier 200 with the first tier 100, a redistribution circuit structure 224 is formed over a backside 200b of the second tier 200. Specifically, the redistribution circuit structure 224 may include a plurality of dielectric layers 226 and a plurality of redistribution conductive layers 228 stacked alternately. A portion of the redistribution conductive layers 228 may be electrically connected with a corresponding portion of the second metal features 208 of the second interconnect structure 204 by at least one through-substrate via (TSV) 225 which penetrates through the second semiconductor substrate 202. Then, at least one pad 264 may be formed over the redistribution circuit structure 224 to electrically connect the redistribution conductive layers 228 of the redistribution circuit structure 224, and a passivation layer 262 may be formed to laterally surround the pad 264.

FIG. 1C illustrates an enlarged cross-sectional view of a region 152 of the semiconductor structure 10 of FIG. 1A.

Referring to FIG. 1C, the first metal layer 118 may include a first non-twinned metal layer 118A and a first twinned metal layer 118B over the first non-twinned metal layer 118A. In some embodiments, the first non-twinned metal layer 118A is non-twinned copper, and the first twinned metal layer 118B is twinned copper. The twinned copper is also referred to as nano-twinned copper or nano-twinned crystal copper. The twinned copper includes (111)-oriented twinned copper, in accordance with some embodiments. That is, the first metal layer 118 has a (111) crystal plane at the first bonding surface 118t. Similarly, the second metal layer 218 may include a second non-twinned metal layer 218A and a second twinned metal layer 218B over the second non-twinned metal layer 218A. In some embodiments, the second non-twinned metal layer 218A is non-twinned copper, and the second twinned metal layer 218B is twinned copper. That is, the second metal layer 218 has a (111) crystal plane at the second bonding surface 218t. The second metal layer 218 may be turned upside down, so that the second bonding surface 218t faces toward the first bonding surface 118t. The second metal layer 218 may be bonded to the first metal layer 118 by direct contacting the second bonding surface 218t with the first bonding surface 118t at a bonding interface IS1.

It should be noted that, in some embodiments, the first metal layer 118 and the second metal layer 218 having nano-twinned copper at bonding interface IS1 allows a subsequent annealing process to be performed at a low temperature and improves the strength of the resulting bonds, thereby increasing the reliability of the semiconductor structure 10 (FIG. 1A). That is, the bonding metal structure (118/218) having nano-twinned copper can effectively reduce the thermal budget and achieve lower resistance than the non-twinned copper. Such Cu—Cu connectors with high bonding strength and low thermal budget can be widely used for advanced ultra-fine-pitch packaging. The forming method and detail configuration of the first metal layer 118 having nano-twinned copper will be subsequently described for FIG. 2A-FIG. 2D.

FIG. 2A to FIG. 2D illustrate cross-sectional views of intermediate stages in the formation of a semiconductor structure in accordance with some embodiments.

Referring to FIG. 2A, the first dielectric layer 116 is formed over the first interconnect structure 104. Specifically, the first dielectric layer 116 may include a first etching stop layer 115A, a first dielectric material 117A, a second etching stop layer 115B, and a second dielectric material 117B in order from bottom to top. In some embodiments, the first etching stop layer 115A and the first dielectric material 117A have dielectric materials with different etch selectivities, while the second etching stop layer 115B and the second dielectric material 117B have dielectric materials with different etch selectivities. For example, the first etching stop layer 115A may include a silicon carbide (SiC) layer, each of the first dielectric material 117A and the second dielectric material 117B may include a silicon oxide layer, and the second etching stop layer 115B may include a silicon nitride (SiN) layer, although other materials may also be used.

Then, a damascene opening 119 is formed in the first dielectric layer 116. Specifically, the damascene opening 119 may include a via hole 119A and a trench 119B on the via hole 119A. The via hole 119A may penetrate through the first dielectric material 117A and the first etching stop layer 115A to expose the first metal feature 108 of the first interconnect structure 104. The trench 119B may penetrate through the second dielectric material 117B and the second etching stop layer 115B to stop on the first dielectric material 117A. In other word, the first dielectric layer 116 may have an inner sidewall defining the via hole 119A and the trench 119B on the via hole 119A. As shown in FIG. 2A, the via hole 119A and the trench 119B are spatially connected to form the damascene opening 119 with a wider upper opening and a narrower lower opening.

In some embodiments, the via hole 119A has a depth D1 of about 0.25 μm, such as in the range of 0.1 μm to 0.3 μm, and a width W1 of about 0.2 μm, such as in the range of 0.1 μm to 0.3 μm. In some embodiments, the trench 119B has a depth D2 of about 0.7 μm, such as in the range of 0.5 μm to 0.9 μm, and a width W2 of about 0.4 μm, such as in the range of 0.3 μm to 0.6 μm. In some embodiments, an aspect ratio (e.g., ratio of depth (D1+D2) to width (W2)) of the damascene opening 119 is in the range of 1-4, such as 1, 2, 3, or 4, although other ranges may also be used.

After forming the damascene opening 119, a first barrier layer 132 is formed over the first dielectric layer 116. Specifically, the first barrier layer 132 may extend along a surface of the damascene opening 119, and further cover a portion of the first metal feature 108 and a top surface of the first dielectric layer 116. In some embodiments, the first barrier layer 132 includes Ti, TiN, Ta, TaN, or a combination thereof, and may be formed by PVD, CVD, or the like. Next, a first seed layer 134 is formed over the first barrier layer 132. In some embodiments, the first seed layer 134 is a conformal seed layer. The first seed layer 134 may be formed by a suitable process, such as CVD or PVD. The PVD may be sputtering, for example. In some embodiments, the first seed layer 134 is a metal layer, which may be a single layer or a composite layer including a plurality of sub-layers formed of different materials. In the present embodiment, the first seed layer 134 is, for example, a titanium/copper composited layer, wherein the sputtered titanium thin film is in contact with the first barrier layer 132, and the sputtered copper thin film is then formed over the sputtered titanium thin film. In some alternative embodiments, the first seed layer 134 is other suitable composited layer such as metal, alloy, or a combination thereof.

Referring to FIG. 2B, a first plating process is performed to form a first non-twinned metal layer 118A in the via hole 119A of the damascene opening 119. Specifically, the first plating process may control so that the first non-twinned metal layer 118A completely fills the via hole 119A but does not fill (or partially fill) the trench 119B. In some embodiments, the first non-twinned metal layer 118A is non-twinned copper formed by the first plating process, such as an electroplating process. The first non-twinned metal layer 118A is formed by submerging the first seed layer 134 in a plating solution. The plating solution may be, e.g., a sulfuric acid electrolyte. The plating solution includes cations of the first non-twinned metal layer 118A (e.g., Cu). An electric current is applied to the plating solution to reduce the cations and thereby form the first non-twinned metal layer 118A. After the first plating process, a thin metal layer (i.e., a portion of the first non-twinned metal layer 118A) is also formed to extend on the first seed layer 134.

Referring to FIG. 2C, a second plating process is performed to form a twinned metal material 128 in the trench 119B of the damascene opening 119 and over the first non-twinned metal layer 118A. Specifically, the second plating process may control so that the twinned metal material 128 completely fills the trench 119B and further extends to cover the top surface of the first dielectric layer 116. In some embodiments, the twinned metal material 128 is nano-twinned copper formed by the second plating process, such as an electroplating process. The twinned metal material 128 is formed by submerging the first non-twinned metal layer 118A in a plating solution. The plating solution may be, e.g., a sulfuric acid electrolyte. The plating solution includes cations of the twinned metal material 128 (e.g., Cu). In some embodiments, the plating solution is used to plate the twinned metal material 128 is the same as or different from that of the first non-twinned metal layer 118A. An electric current is applied to the plating solution to reduce the cations and thereby form the twinned metal material 128.

In some embodiments, a plating current of the second plating process is less than a plating current of the first plating process. In this case, the lower plating current allows the plated conductive material to have a uniform grain orientation, such as (111) crystal plane. A copper layer with a uniform grain orientation may be referred to as a nano-twinned copper layer. The twinned metal material 128 with the uniform grain orientation allows a subsequent bonding process to be performed at a low temperature, thereby reducing the thermal budget and achieving lower resistance. In some embodiments, the plating current of the second plating process is in the range of 0.1 A to 5.0 A, 0.1 A to 4.0 A, 0.1 A to 3.0 A, 0.1 A to 2.0 A, or 0.1 A to 1.0 A. In some alternative embodiments, the plating current of the second plating process may be greater than or equal to the plating current of the first plating process. In some other embodiments, the second plating process may be a pulse electroplating process.

Referring to FIG. 2D, performing a planarization process on the twinned metal material 128 to remove a portion of the twinned metal material 128 to from a first twinned metal layer 118B over the first non-twinned metal layer 118A. In some embodiments, the planarization process includes a chemical mechanical polish (CMP), an etch-back process, combinations thereof, or the like. The planarization process is performed until a top surface 118t of the first twinned metal layer 118B is substantially level (within process variations) with a top surface 116t of the first dielectric layer 116. In addition, the planarization process further remove portions of the first non-twinned metal layer 118A, the first seed layer 134, and the first barrier layer 132 over the top surface 116t of the first dielectric layer 116. After the planarization process, the substantially coplanar top surfaces of the first dielectric layer 116 and the first metal layer 118 are at the frontside 100f of the first tier 100 (FIG. 1A), which will be used for a subsequent bonding process.

In some embodiments, when the twinned metal material is formed in the opening with a high aspect ratio (e.g., greater than 0.5), the proportion of the twinned metal material with (111) crystal plane decreases as the aspect ratio increases. That is, the twinned metal material with (111) orientation is not suitable for deposition in the opening with high aspect ratio. In this case, the first metal layer 118 with a bi-layered structure can solve the said issue. In detail, the first non-twinned metal layer 118A is firstly formed in the damascene opening 119 to decrease the aspect ratio of the damascene opening 119, and the first twinned metal layer 118B is then formed in the trench 119B with lower aspect ratio to maintain the ratio of the (111) orientation in the first twinned metal layer 118B. In such embodiment, more than 99% of the volume percent of the first twinned metal layer 118B are <111> oriented, and the first twinned metal layer 118B with the uniform grain orientation allows the subsequent bonding process to be performed at a low temperature, thereby reducing the thermal budget and achieving lower resistance. In some embodiments, a ratio of a height of the first twinned metal layer 118B to a total height of the first metal layer 118 is in a range of 30% to 100%.

FIG. 2E-FIG. 2G are various views of a bonding structure in accordance with some embodiments.

FIG. 2E illustrates an enlarged cross-sectional view of a region 120 of the first metal layer 118 of FIG. 2D. In some embodiments, the first metal layer 118 may include a first non-twinned metal layer 118A, a first twinned metal layer 118B, and a first transition layer 118C sandwiched between the first non-twinned metal layer 118A and the first twinned metal layer 118B. The first transition layer 118C may extend along a bottom surface of the first twinned metal layer 118B and further laterally surrounds a sidewall of the first twinned metal layer 118B. After the planarization process, the top surface of the first twinned metal layer 118B is substantially level (within process variations) with a top surface of the first transition layer 118C.

FIG. 2F illustrates a portion of the first metal layer 118, including the first transition layer 118C and the first twinned metal layer 118B over the first transition layer 118C. The first twinned metal layer 118B may include a plurality of nanopillars 152 therein. The nanopillars 152 are elongated in the vertical direction and form pillars in at the nanometer scale. The nanopillars 152 have boundaries that are clear and distinguishable, for example, when viewed in X Ray Diffraction (XRD) images or Electron Back Scatter Diffraction (EBSD) images. Specifically, the nanopillars 152 are separated from each other by vertical boundaries. The nanopillars 152 may (or may not) extend away from the top surface of the first transition layer 118C to the top surface of first twinned metal layer 118B. The edges of the nanopillars 152 are substantially vertical, and may (or may not) be slightly curved or tilted, with the general trend being upward from the first transition layer 118C.

FIG. 2F also illustrates details in some of the nanopillars 152. In some embodiments, each nanopillar 152 includes a plurality of nanosheets 154 stacked up in the vertical direction to form the nanopillar 152. The nanosheets 154 have interfaces that are clearly distinguishable, for example, when viewed in XRD images or EBSD images. The top and bottom surfaces of nanosheets 154 in a nanopillar 152 may be level with, higher than, or lower than (in a random way) the top and bottom surfaces of their contacting nanosheets 154 in neighboring nanopillars 152. In some embodiments, all of the nanopillars 152 have clearly distinguishable edges (for example, in XRD images or EBSD images) contacting the edges of the neighboring nanopillars 152. The edges are also substantially vertical. In other embodiments, most of the nanopillars 152 have clearly distinguishable edges (which are substantially vertical) to separate them from the neighboring nanopillars 152, while a small amount of nanosheets 154 may extend into neighboring nanopillars 152. For example, some of the nanosheets 154 in two neighboring nanopillars 152 may merge with each other such that no distinguishable edges separate them from each other.

FIG. 2G illustrates the crystal structure of the first non-twinned metal layer 118A, the crystal structure of the first twinned metal layer 118B, and the crystal structure of the first transition layer 118C sandwiched between the first non-twinned metal layer 118A and the first twinned metal layer 118B. Specifically, the crystal structure of adjacent two nanopillars 152 in the first twinned metal layer 118B is shown. Other nanopillars 152 are omitted for illustration clarity.

The first non-twinned metal layer 118A has a polycrystalline structure including a plurality of grains 136 therein. Each of the grains 136 has a crystalline structure that is different from and/or misaligned from the crystalline structure of its neighboring grains 136 to form boundaries. The grains 136 inside the first non-twinned metal layer 118A may have shapes different from each other and sizes different from each other. The boundaries of the grains 136 inside the first non-twinned metal layer 118A are irregular (random without repeating patterns) and are not aligned to each other, such that the pattern of the grains 136 is irregular. The irregular pattern of the grains 136 is distributed throughout the first non-twinned metal layer 118A. The grains 136 of the first non-twinned metal layer 118A have a non-uniform orientation. Specifically, the grains 136 of the first non-twinned metal layer 118A have random lattice orientations. As such, no majority of the grains 136 of the first non-twinned metal layer 118A has a same lattice direction.

Each nanosheet 154 has a polycrystalline structure including a plurality of grains 156 therein. Each of the grains 156 has a crystalline structure that is different from and/or misaligned from the crystalline structure of its neighboring grains 156 to form boundaries. The grains 156 inside each nanosheet 154 may have shapes different from each other and sizes different from each other. The boundaries of the grains 156 inside each nanosheet 154 are irregular (random without repeating patterns), and are not aligned to each other. The irregular pattern of the grains 156 in each nanosheet 154 is distributed throughout the nanosheet 154. The top surfaces of the top grains 156 inside each nanosheet 154 are substantially coplanar with each other to form a substantially planar top surface of the nanosheet 154, which also forms a planar interface with its overlying nanosheet 154. In some embodiments, the top surfaces of the top grains 156 of a nanosheet 154 have height variations smaller than about 5 percent of the thickness T1. Similarly, the bottom surfaces of the bottom grains 156 inside each nanosheet 154 are substantially coplanar with each other to form a substantially planar bottom surface of the nanosheet 154. The edges of the grains 156 at a sidewall of a nanosheet 154 are also substantially aligned to form substantially vertical edges. Accordingly, in the cross-sectional view, each nanosheet 154 may have a rectangular shape with clearly distinguishable boundaries. The nanosheets 154 are separated from each other by horizontal boundaries.

The grains 156 of the nanosheets 154 have a uniform orientation. Specifically, the majority of the grains 156 of the nanosheets 154 may have a same lattice direction, which may be in <111> crystal plane. In some embodiments, more than 99% of the volume percent of the grains 156 are <111> oriented, while the rest of the percent (by volume) of the grains 156 have other lattice orientations. For example, the volume percent of the grains 156 with (111) crystal plane of the nanosheets 154 is in the range of 99% to 100%, such as 99.1%, 99.2%, 99.3%, 99.4%, 99.5%, 99.6%, 99.7%, 99.8%, 99.9%. When the majority of the grains 156 of the nanosheets 154 have a same lattice direction and no majority of the grains 136 of the first non-twinned metal layer 118A have a same lattice direction, the grains 156 of the nanosheets 154 may be said to have a greater uniformity than the grains 136 of the first non-twinned metal layer 118A.

In some embodiments, the first transition layer 118C has a polycrystalline structure including a plurality of grains 146 therein. Each of the grains 146 has a crystalline structure that is different from and/or misaligned from the crystalline structure of its neighboring grains 146 to form boundaries. The grains 146 inside the first transition layer 118C may have shapes different from each other and sizes different from each other. The boundaries of the grains 146 inside the first transition layer 118C are irregular (random without repeating patterns) and are not aligned to each other, such that the pattern of the grains 146 is irregular. The irregular pattern of the grains 146 is distributed throughout the first transition layer 118C. In some embodiments, a twinned metal ratio of the first transition layer 118C gradually increases along a direction from the first non-twinned metal layer 118A toward the first twinned metal layer 118B.

As shown in FIG. 2G, an average grain size of the first non-twinned metal layer 118A is greater than an average grain size of the first transition layer 118C, and the average grain size of the first transition layer 118C is greater than an average grain size of the first twinned metal layer 118B, in accordance with some embodiments. Herein, the grain size of the first twinned metal layer 118B may be referred to as the grain size of a single nanosheet 154 in the vertical direction. That is, the grains 156 of the nanosheets 154 may be said to have a greater uniformity than the grains 146 of the first transition layer 118C, and the grains 146 of the first transition layer 118C may be said to have a greater uniformity than the grains 136 of the first non-twinned metal layer 118A.

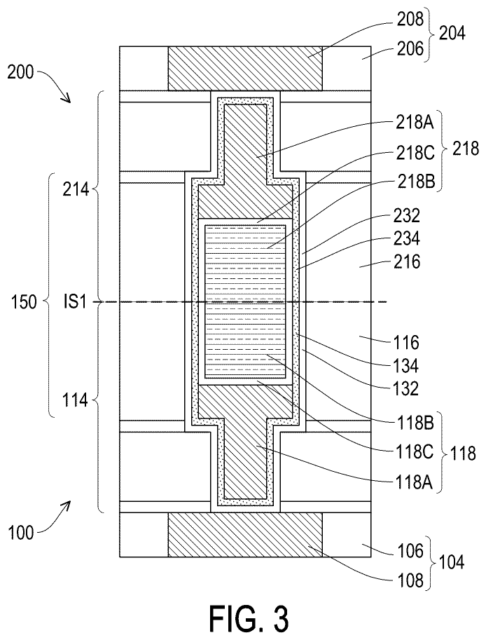

FIG. 3 is a cross-sectional view of a semiconductor structure, such as a wafer stack with a bonding structure 150 for example. The wafer stack includes two of the ICs including the first tier 100 and the second tier 200 (details shown in FIG. 1A) that are bonded in a face-to-face manner. However, the embodiments of the present disclosure are not limited thereto, in other embodiments, the first tier 100 and the second tier 200 may be bonded in a face-to-back manner, a back-to-face manner or a back-to-back manner. That is, more than two ICs may be stacked to each other in the face-to-face manner, the face-to-back manner, the back-to-face manner or the back-to-back manner. The wafer stack may be part of a package structure, such as a system-on-integrated-chip (SoIC) package structure or the like.

As an example of the bonding process, the first tier 100 may be bonded to the second tier 200 by direct bonding. The first dielectric layer 116 is in direct contact with the second dielectric layer 216 through dielectric-to-dielectric bonding, without using any adhesive material (e.g., die attach film). The first metal layer 118 is in direct contact with the second metal layer 218 through metal-to-metal bonding, without using any eutectic material (e.g., solder). The bonding may include a pre-bonding and an annealing. During the pre-bonding, a small pressing force is applied to press the first tier 100 and the second tier 200 against one another. The bonding strength is then improved in a subsequent annealing step, in which the dielectric layers 116, 216 and the metal layers 118, 218 are annealed. After the annealing, direct bonds such as fusion bonds are formed, bonding the first dielectric layer 116 to the second dielectric layer 216. For example, the bonds can be covalent bonds between the material of the first dielectric layer 116 and the material of the second dielectric layer 216. The first metal layer 118 and the second metal layer 218 may be in physical contact after the pre-bonding, or may expand to be brought into physical contact during the annealing. Further, during the annealing, the material of the first metal layer 118 and the second metal layer 218 (e.g., copper) intermingles, so that metal-to-metal bonds are also formed. Hence, the resulting bonds between the first tier 100 and the second tier 100B are hybrid bonds that include both dielectric-to-dielectric bonds and metal-to-metal bonds.

In some embodiments, the second metal layer 218 may include a second non-twinned metal layer 218A, a second twinned metal layer 218B, and a second transition layer 218C sandwiched between the second non-twinned metal layer 218A and the second twinned metal layer 218B. The bonding surface of the first metal layer 118 include the bonding surface of the first non-twinned metal layer 118A (e.g., the nano-twinned copper layer), and the bonding surface of the second metal layer 218 also include the bonding surface of the second non-twinned metal layer 218A (e.g., the nano-twinned copper layer). Nano-twinned copper layers may intermingle at a lower temperature and a lower pressure than non-twinned copper layers. As such, the first metal layer 118 and the second metal layer 218 may be annealed at a low temperature during the bonding process. Additionally, the first metal layer 118 and the second metal layer 218 may be annealed for a short duration during the bonding process. The bonding process is a low-temperature bonding process. In this context, a low-temperature bonding process is a bonding process performed at a temperature of less than about 300° C. In some embodiments, the dielectric layers 116, 216 and the metal layers 118, 218 are annealed at a temperature in the range of 150° C. to 250° C. during the bonding process. Utilizing a low-temperature bonding process may improve the reliability of the resulting wafer stack and improve the ease of wafer integration. Additionally, nano-twinned copper can withstand greater tensile strain and has greater electromigration than non-twinned copper. As such, the bonding strength between the metal layers 118, 218 is large, and the bonding strength does not significantly decrease as a result of any subsequently performed thermal annealing processes. After the annealing, the thin non-twinned metal layer (a portion of 118A shown in FIG. 2D) on the sidewall of the first twinned metal layer 118B may be intermingled with the first seed layer 134 into a single film layer, so only the first seed layer 134 is illustrated in FIG. 3.

When the material of the metal layers 118, 218 intermingles during bonding, pairs of the metal layers 118, 218 form respective bonding metal structure. Specifically, the first twinned metal layer 118B may be in contact with the second twinned metal layer 218B and the first transition layer 118C may be in contact with the second transition layer 218C at the bonding interface IS1, while the laterally offset (within process variations) between the metal layers 118, 218 is acceptable. Further, the first barrier layer 132 may be in contact with the second barrier layer 232 and the first seed layer 134 may be in contact with the second seed layer 234 at the bonding interface IS1. Similarly, when the material of the dielectric layers 116, 216 intermingles during bonding, the dielectric layers 116, 216 form a bonding dielectric structure. The bonding metal structure is embedded in the bonding dielectric structure to form the bonding structure 150.

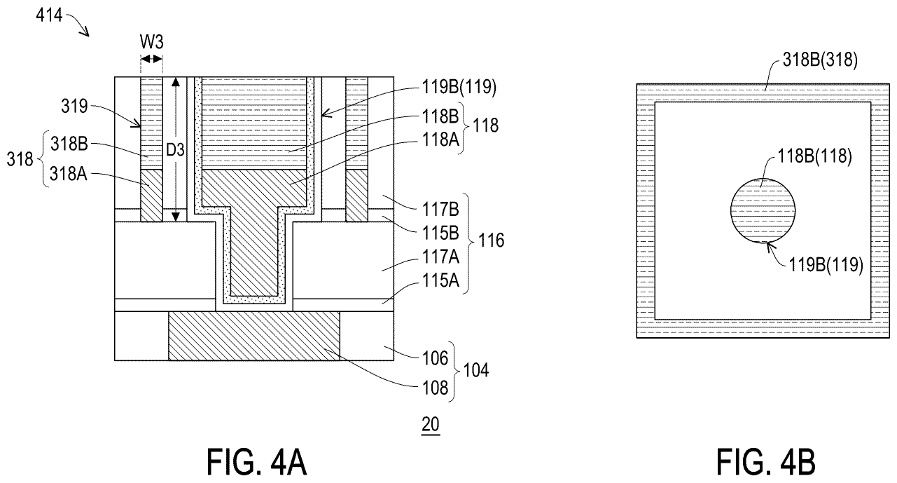

FIG. 4A and FIG. 4B illustrate a cross-sectional view and a top view of a semiconductor structure in accordance with some alternative embodiments.

Referring to FIG. 4A, a semiconductor structure 20 with a bonding layer 414 is provided. The arrangement, material and forming method of the bonding layer 414 are similar to the arrangement, material and forming method of the first bonding layer 114 illustrated in FIG. 3. Thus, details thereof are omitted here. The main difference between the bonding layer 414 and the first bonding layer 114 lies in that the bonding layer 414 further includes a shielding ring 318 embedded in the first dielectric layer 116. Specifically, the shielding ring 318 may laterally surround the trench 119B of the damascene opening 119, as shown in the top view of FIG. 4B. In some embodiments, the first metal layer 118 is used for signal transmission between the first tier 100 and the second tier 200 (FIG. 1A). The shielding ring 318 may laterally surround the first metal layer 118, and be used as a shielding structure capable of preventing electromagnetic interference (EMI) caused by the first metal layer 118, thereby decreasing the undesired noise and improve the performance of the semiconductor structure 20. In some embodiments, the shielding ring 318 is electrically connected to ground or bias according to the needs. Although the shielding ring 318 illustrated in FIG. 4B is a rectangular ring structure, the embodiments of the present disclosure are not limited thereto. In other embodiments, the shielding ring 318 may be a ring structure with any top-view shape.

It should be noted that, in some embodiments, the shielding ring 318 may be formed with the first metal layer 118 in the same plating process. In this case, the shielding ring 318 also includes a third non-twinned metal layer 318A and a third twinned metal layer 318B over the third non-twinned metal layer 318A. Further, the shielding ring 318 also includes a third transition layer (not shown) between the third non-twinned metal layer 318A and the third twinned metal layer 318B. The configuration, crystal structure, material and forming method of the shielding ring 318 are similar to the arrangement, material and forming method of the first metal layer 118 illustrated in FIG. 2E-FIG. 2G. Thus, details thereof are omitted here.

In some embodiments, the ring hole 319 has a depth D3 of about 0.7 μm, such as in the range of 0.5 μm to 0.9 μm, and a width W3 of about 0.1 μm, such as in the range of 0.05 μm to 0.3 μm. In some embodiments, an aspect ratio (e.g., ratio of depth (D3) to width (W3)) of the ring hole 319 is in the range of 1.7-18, 1.7-10, 3-10, or 3-18, although other ranges may also be used. In some embodiments, the twinned metal material with (111) orientation is not suitable for deposition in the opening with high aspect ratio. In this case, the third non-twinned metal layer 318A is firstly formed in the ring hole 319 to decrease the aspect ratio value of the ring hole 319, and the third twinned metal layer 318B is then formed on the third non-twinned metal layer 318A to maintain the ratio of the (111) orientation in the third twinned metal layer 318B. In such embodiment, more than 99% of the volume percent of the third twinned metal layer 318B are <111> oriented, and the third twinned metal layer 318B with the uniform grain orientation allows the subsequent bonding process to be performed at a low temperature, thereby reducing the thermal budget and achieving lower resistance.

After forming the bonding layer 414, the subsequent bonding process may be performed to form a wafer stack as shown in FIG. 3, thereby accomplishing the semiconductor structure 20.

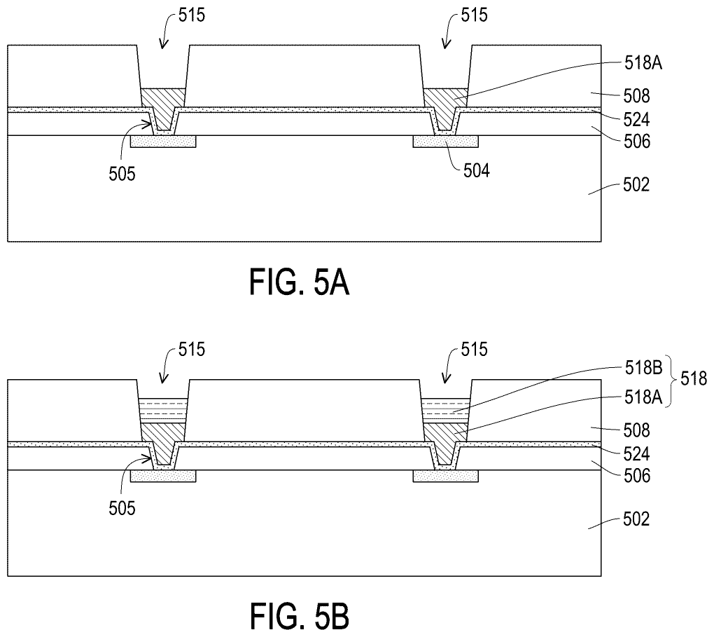

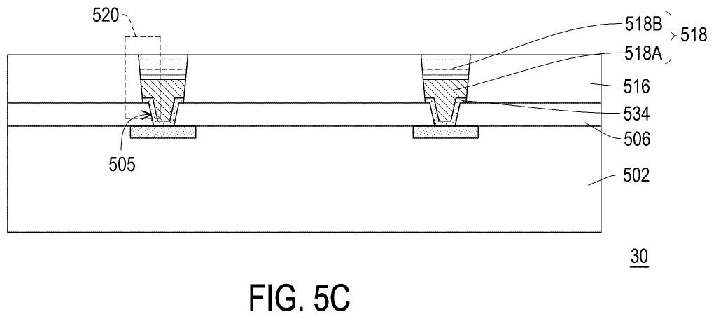

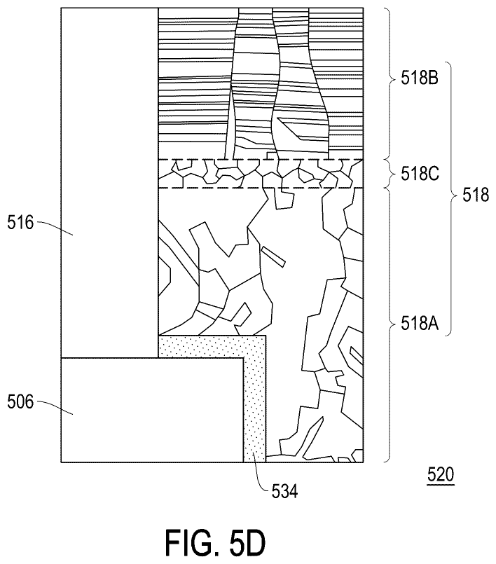

FIG. 5A to FIG. 5D illustrate cross-sectional views of intermediate stages in the formation of a semiconductor structure in accordance with some other embodiments.

Referring to FIG. 5A, a die 502 having a plurality of contacts 504 is provided. A first dielectric material 506 having a plurality of via openings 505 is formed on the die 502. Then, a seed material 524 is formed on the die 502. The seed material 524 conformally covers the top surface of the first dielectric material 506 and the surface of the via openings 505. In some embodiments, the seed material 524 is, for example, a titanium/copper composited layer, wherein the sputtered titanium thin film is in contact the contacts 504 of the die 502, and the sputtered copper thin film is then formed over the sputtered titanium thin film. Next, a photoresist layer 508 having a plurality of trench openings 515 is formed on the seed material 524. Thereafter, a first plating process is performed to form a first non-twinned metal layer 518A in the via openings 505.

Referring to FIG. 5B, a second plating process is performed to form a first twinned metal layer 518B in the trench openings 515 and over the first non-twinned metal layer 518A, thereby accomplishing a first metal layer 518.

Referring to FIG. 5B and FIG. 5C, the photoresist layer 508 is removed and the seed material 524 uncovered by the first metal layer 518 is also removed, thereby revealing the first metal layer 518 in which a seed layer 534 covers the bottom of the first metal layer 518. Then, a second dielectric material 516 is formed on the first dielectric material 506 to laterally surround the first metal layer 518.

FIG. 5D illustrates an enlarged cross-sectional view of a region 520 of the first metal layer 518 of FIG. 5C. In some embodiments, the first metal layer 518 may include a first non-twinned metal layer 518A, a first twinned metal layer 518B, and a first transition layer 518C sandwiched between the first non-twinned metal layer 118A and the first twinned metal layer 118B. The first transition layer 518C only extend along a bottom surface of the first twinned metal layer 518B, but not laterally surrounds a sidewall of the first twinned metal layer 518B. In addition, the seed layer 534 only covers the bottom of the first non-twinned metal layer 518A, but not cover the sidewalls of the first twinned metal layer 518B and the first transition layer 518C.

After forming a bonding layer 514 with the first metal layer 518, the subsequent bonding process may be performed to form a die stack as shown in FIG. 3, thereby accomplishing the semiconductor structure 30.

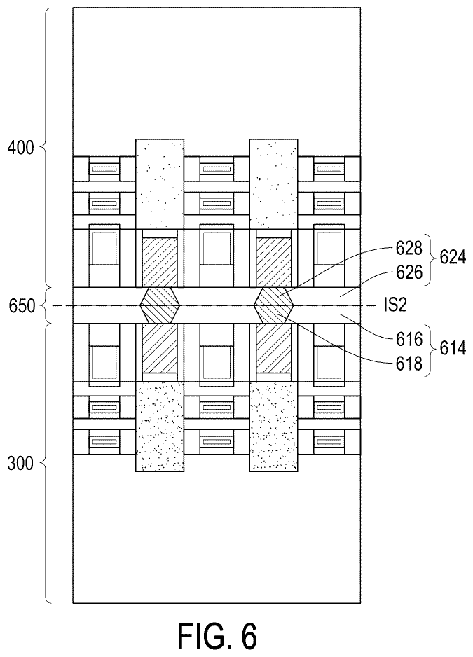

FIG. 6 illustrates a cross-sectional view of a semiconductor structure in accordance with some alternative embodiments.

In addition to the above exemplary embodiments of the wafer stack and die stack, the bonding metal layer with the bi-layered structure may also be applied in complementary field effect transistors (CFETs). In some embodiments, a CFET includes a n-type transistor and a p-type transistor that are vertically stacked together. An intermetal structure is formed between the n-type transistor and the p-type transistor to facilitate electrical connections between the stacked transistors. Specifically, gate contacts may be formed through gates of the n-type transistor and the p-type transistor, and a conductive line in the intermetal structure may electrically connect the gate contacts together. Likewise, source/drain contacts may be formed through source/drain regions of the n-type transistor and the p-type transistor, and a conductive line in the intermetal structure may electrically connect the source/drain contacts together. In this manner, routing distance between gates and/or source/drain regions of the stacked transistors can be reduced, and contact resistance can be reduced.

Referring to FIG. 6, a semiconductor structure 40 is provided. In some embodiments, the semiconductor structure 40 includes a third tier 300, a fourth tier 400, and a bonding structure 650. The third tier 300 may be bonded to the fourth tier 400 by the bonding structure 650.

In some embodiments, one of the third tier 300 and the fourth tier 400 may include a vertically stacked nanostructure-FET (e.g., nanowire FET, nanosheet FET, multi bridge channel (MBC) FET, nanoribbon FET, gate-all-around (GAA) FET, or the like). For example, the third tier 300 may include a lower nanostructure-FET of a first device type (e.g., n-type/p-type) and the fourth tier 400 may include an upper nanostructure-FET of a second device type (e.g., p-type/n-type) that is opposite the first device type. Specifically, the third tier 300 may include a lower PMOS transistor and the fourth tier 400 may include an upper NMOS transistor, or the third tier 300 may include a lower NMOS transistor and the fourth tier 400 may include an upper PMOS transistor.

In some embodiments, the bonding structure 650 may include a third bonding layer 614 in direct contact with a fourth bonding layer 624. The third bonding layer 614 may include a third bonding metal layer 618 embedded in the third dielectric layer 616, and the fourth bonding layer 624 may include a fourth bonding metal layer 628 embedded in the fourth dielectric layer 626. Each of the third bonding metal layer 618 and the fourth bonding metal layer 628 has a bi-layered structure including a non-twinned metal layer and a twinned metal layer over the non-twinned metal layer, as shown in FIG. 2E or FIG. 5D. The twinned metal layer may have the (111) crystal plane at a bonding interface IS2, which allows a subsequent annealing process to be performed at a low temperature, thereby reducing the thermal budget and achieving lower resistance.

According to some embodiments, a bonding structure includes: a first dielectric layer having a first inner sidewall defining a first via hole and a first trench on the first via hole; a first non-twinned metal layer filling in the first via hole; a first twinned metal layer disposed over the first non-twinned metal layer and within the first trench; and a first transition layer sandwiched between the first non-twinned metal layer and the first twinned metal layer.

In some embodiments, a first bonding surface of the first twinned metal layer exposed by a top surface of the first dielectric layer has a (111) crystal plane. In some embodiments, the first twinned metal layer comprises a plurality of nanopillars extending upward from the first transition layer, each nanopillar has a plurality of nanosheets stacked alternately, and more than 99% of the volume percent of each nanosheet has the same lattice orientation. In some embodiments, an average grain size of the first non-twinned metal layer is greater than an average grain size of the first transition layer, and the average grain size of the first transition layer is greater than an average grain size of the first twinned metal layer. In some embodiments, further comprising: a barrier layer extending along the first inner sidewall of the first dielectric layer; and a first seed layer sandwiched between the first barrier layer and the first non-twinned metal layer, and between the first barrier layer and the first twinned metal layer, and wherein the first transition layer further laterally surrounds a sidewall of the first twinned metal layer. In some embodiments, further comprising: a first seed layer lining a surface of the first via hole, sandwiched between the first dielectric layer and the first non-twinned metal layer, and not extending on a sidewall of the first twinned metal layer. In some embodiments, further comprising: a second dielectric layer having a second inner sidewall defining a second via hole and a second trench on the second via hole; a second non-twinned metal layer filling in the second via hole; a second twinned metal layer disposed over the second non-twinned metal layer and within the second trench; and a second transition layer sandwiched between the second non-twinned metal layer and the second twinned metal layer, wherein the second non-twinned metal layer is in direct contact with the first non-twinned metal layer to form a bonding metal structure, and the second dielectric layer is in direct contact with the first dielectric layer to form a bonding dielectric layer. In some embodiments, further comprising: a shielding ring embedded in the first dielectric layer to laterally surround the first trench, wherein the shielding ring comprises a third non-twinned metal layer, a third twinned metal layer over the third non-twinned metal layer, and a third transition layer sandwiched between the third non-twinned metal layer and the third twinned metal layer.

According to some embodiments, a semiconductor structure includes: a first integrated circuit comprising: a first dielectric layer; and a first bonding metal layer embedded in the first dielectric layer and having a first bonding surface exposed by the first dielectric layer, wherein the first bonding metal layer has a (111) crystal plane at the first bonding surface; and a second integrated circuit comprising: a second dielectric layer directly contacting the first dielectric layer; and a second bonding metal layer embedded in the second dielectric layer and having a second bonding surface exposed by the second dielectric layer, wherein the second bonding surface is in direct contact with the first bonding surface.

In some embodiments, the second bonding metal layer has a (111) crystal plane at the second bonding surface. In some embodiments, the first bonding metal layer comprises: a first non-twinned metal layer; a first twinned metal layer disposed over the first non-twinned metal layer; and a first transition layer sandwiched between the first non-twinned metal layer and the first twinned metal layer, wherein a top surface of the first twinned metal layer is the first bonding surface. In some embodiments, the first twinned metal layer comprises a plurality of nanopillars extending upward from the first transition layer, each nanopillar has a plurality of nanosheets stacked alternately, and more than 99% of the volume percent of each nanosheet has the same lattice orientation. In some embodiments, an average grain size of the first non-twinned metal layer is greater than an average grain size of the first transition layer, and the average grain size of the first transition layer is greater than an average grain size of the first twinned metal layer. In some embodiments, the first transition layer further laterally surrounds a sidewall of the first twinned metal layer. In some embodiments, a twinned metal ratio of the first transition layer gradually increases along a direction from the first non-twinned metal layer toward the first twinned metal layer. In some embodiments, a material of one of the first and second bonding metal layers comprises copper, tungsten, cobalt, or a combination thereof.

According to some embodiments, a method includes: forming a first damascene opening in a first dielectric layer; performing a first plating process to form a first non-twinned metal layer in the first damascene opening; and performing a second plating process to form a first transition layer and a first twinned metal layer in the first damascene opening and over the first non-twinned metal layer, wherein a plating current of the second plating process is less than a plating current of the first plating process.

In some embodiments, further comprising: performing a planarization process so that a top surface of the first twinned metal layer is substantially level with a top surface of the first dielectric layer. In some embodiments, an average grain size of the first non-twinned metal layer is greater than an average grain size of the first transition layer, and the average grain size of the first transition layer is greater than an average grain size of the first twinned metal layer. In some embodiments, further comprising: forming a second damascene opening in a second dielectric layer; forming a second non-twinned metal layer in the second damascene opening; and forming a second transition layer and a second twinned metal layer in the second damascene opening and over the second non-twinned metal layer; and forming a bonding structure by directing contacting the second twinned metal layer with the first twinned metal layer and directing contacting the second dielectric layer with the first dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A bonding structure, comprising:
a first dielectric layer having a first inner sidewall defining a first via hole and a first trench on the first via hole;
a first non-twinned metal layer filling in the first via hole;
a first twinned metal layer disposed over the first non-twinned metal layer and within the first trench; and
a first transition layer sandwiched between the first non-twinned metal layer and the first twinned metal layer.

2. The bonding structure of claim 1, wherein a first bonding surface of the first twinned metal layer exposed by a top surface of the first dielectric layer has a (111) crystal plane.

3. The bonding structure of claim 1, wherein the first twinned metal layer comprises a plurality of nanopillars extending upward from the first transition layer, each nanopillar has a plurality of nanosheets stacked alternately, and more than 99% of the volume percent of each nanosheet has the same lattice orientation.

4. The bonding structure of claim 1, wherein an average grain size of the first non-twinned metal layer is greater than an average grain size of the first transition layer, and the average grain size of the first transition layer is greater than an average grain size of the first twinned metal layer.

5. The bonding structure of claim 1, further comprising:
a barrier layer extending along the first inner sidewall of the first dielectric layer; and
a first seed layer sandwiched between the first barrier layer and the first non-twinned metal layer, and between the first barrier layer and the first twinned metal layer, and wherein the first transition layer further laterally surrounds a sidewall of the first twinned metal layer.

6. The bonding structure of claim 1, further comprising:
a first seed layer lining a surface of the first via hole, sandwiched between the first dielectric layer and the first non-twinned metal layer, and not extending on a sidewall of the first twinned metal layer.

7. The bonding structure of claim 1, further comprising:
a second dielectric layer having a second inner sidewall defining a second via hole and a second trench on the second via hole;
a second non-twinned metal layer filling in the second via hole;
a second twinned metal layer disposed over the second non-twinned metal layer and within the second trench; and
a second transition layer sandwiched between the second non-twinned metal layer and the second twinned metal layer,
wherein the second non-twinned metal layer is in direct contact with the first non-twinned metal layer to form a bonding metal structure, and the second dielectric layer is in direct contact with the first dielectric layer to form a bonding dielectric layer.

8. The bonding structure of claim 1, further comprising: a shielding ring embedded in the first dielectric layer to laterally surround the first trench, wherein the shielding ring comprises a third non-twinned metal layer, a third twinned metal layer over the third non-twinned metal layer, and a third transition layer sandwiched between the third non-twinned metal layer and the third twinned metal layer.

9. A semiconductor structure, comprising:
a first integrated circuit comprising:
a first dielectric layer; and
a first bonding metal layer embedded in the first dielectric layer and having a first bonding surface exposed by the first dielectric layer, wherein the first bonding metal layer has a (111) crystal plane at the first bonding surface; and
a second integrated circuit comprising:
a second dielectric layer directly contacting the first dielectric layer; and
a second bonding metal layer embedded in the second dielectric layer and having a second bonding surface exposed by the second dielectric layer, wherein the second bonding surface is in direct contact with the first bonding surface.

10. The semiconductor structure of claim 9, wherein the second bonding metal layer has a (111) crystal plane at the second bonding surface.

11. The semiconductor structure of claim 9, wherein the first bonding metal layer comprises:
a first non-twinned metal layer;
a first twinned metal layer disposed over the first non-twinned metal layer; and
a first transition layer sandwiched between the first non-twinned metal layer and the first twinned metal layer, wherein a top surface of the first twinned metal layer is the first bonding surface.

12. The semiconductor structure of claim 11, wherein the first twinned metal layer comprises a plurality of nanopillars extending upward from the first transition layer, each nanopillar has a plurality of nanosheets stacked alternately, and more than 99% of the volume percent of each nanosheet has the same lattice orientation.

13. The semiconductor structure of claim 11, wherein an average grain size of the first non-twinned metal layer is greater than an average grain size of the first transition layer, and the average grain size of the first transition layer is greater than an average grain size of the first twinned metal layer.

14. The semiconductor structure of claim 11, wherein the first transition layer further laterally surrounds a sidewall of the first twinned metal layer.

15. The semiconductor structure of claim 11, wherein a twinned metal ratio of the first transition layer gradually increases along a direction from the first non-twinned metal layer toward the first twinned metal layer.

16. The semiconductor structure of claim 11, wherein a material of one of the first and second bonding metal layers comprises copper, tungsten, cobalt, or a combination thereof.

17. A method, comprising:
forming a first damascene opening in a first dielectric layer;
performing a first plating process to form a first non-twinned metal layer in the first damascene opening; and
performing a second plating process to form a first transition layer and a first twinned metal layer in the first damascene opening and over the first non-twinned metal layer,
wherein a plating current of the second plating process is less than a plating current of the first plating process.

18. The method of claim 17, further comprising: performing a planarization process so that a top surface of the first twinned metal layer is substantially level with a top surface of the first dielectric layer.

19. The method of claim 17, wherein an average grain size of the first non-twinned metal layer is greater than an average grain size of the first transition layer, and the average grain size of the first transition layer is greater than an average grain size of the first twinned metal layer.

20. The method of claim 17, further comprising:
forming a second damascene opening in a second dielectric layer;
forming a second non-twinned metal layer in the second damascene opening; and
forming a second transition layer and a second twinned metal layer in the second damascene opening and over the second non-twinned metal layer; and
forming a bonding structure by directing contacting the second twinned metal layer with the first twinned metal layer and directing contacting the second dielectric layer with the first dielectric layer.
